(19) United States
(12) Patent Application Publication
(10) Pub. No.: US 2014/0302443 A1
(43) Pub. Date: Oct. 9, 2014

(54) DRAWING APPARATUS, AND METHOD OF MANUFACTURING ARTICLE

(71) Applicant: CANON KABUSHIKI KAISHA, Tokyo (JP)

(72) Inventor: Shinji OHISHI, Oyama-shi (JP)

(73) Assignee: CANON KABUSHIKI KAISHA, Tokyo (JP)

(21) Appl. No.: 14/219,121

(22) Filed: Mar. 19, 2014

(30) Foreign Application Priority Data
Apr. 5, 2013 (JP) 2013-079925

(51) Int. Cl. H01J 37/302

(52) U.S. Cl. CPC H01J 37/3023; H01J 37/3174
USPC 430/325; 250/492.22

(57) ABSTRACT

The present invention provides a drawing apparatus which performs drawing on a substrate with a charged particle beam, including a transmission unit including a plurality of channels and configured to transmit drawing data via the plurality of channels, a plurality of storages respectively corresponding to the plurality of channels, and configured to respectively store the drawing data transmitted via the plurality of channels, and a controller (21;14) configured to control at least either one of transmission start time and a transmission rate of the drawing data from the transmission unit with respect to each of the plurality of storages.

### BACKGROUND OF THE INVENTION

1. Field of the Invention

The present invention relates to a drawing apparatus, and a method of manufacturing an article.

2. Description of the Related Art

Recently, the line widths of patterns (circuits) in semiconductor integrated circuits are decreasing for higher integration degrees. To form a micropattern, drawing apparatuses using charged particle beams such as an electron beam have been developed.

In a certain type of drawing apparatus, a charged particle beam radiated from a charged particle source is split into a plurality of charged particle beams by an aperture array, and charged particle beams each having a small spot diameter of several nm on a substrate are formed via a charged particle optical system. A plurality of charged particle beams irradiating a substrate are controlled to be deflected at once by a deflector. The respective charged particle beams are ON/OFF-controlled by a blanking deflector based on drawing data.

In the drawing apparatus, drawing data corresponding to a pattern to be drawn needs to be stored (held) in a storage device, instead of a mask (reticle) on which a pattern is formed. As the line width of a pattern decreases, the data amount (processing amount) of drawing data tends to increase abruptly. To efficiently process such an enormous amount of data, Japanese Patent Laid-Open No. 2004-63870 proposes a data processing system including two buffer memories. This data processing system parallelly executes a step of reading out data from one memory (that is, performing drawing), and a step of writing (storing) data (data for the next drawing) in the other memory.

To solve the problem that the data amount of drawing data increases, for example, the data amount may be reduced by converting drawing data from bitmap data into vector data, or data may be compressed and stored in the memory. However, a drawing pattern is not uniform, so the data amount on a channel for transmitting drawing data varies.

When an arrangement in which data are written in all memories at the same timing, if the data amount greatly varies between channels, transmission (write) of data in the memory may not be completed in a predetermined period. Also, when data are written in all memories, the electric power consumption of the memories increases (reaches the peak). If a large-size power supply is installed to cope with such electric power consumption, this increases the cost and installation area. Further, large electric power consumption increases noise and may cause a malfunction of an electric circuit or the like.

### SUMMARY OF THE INVENTION

The present invention provides, for example, a drawing apparatus advantageous to transmission of drawing data.

According to one aspect of the present invention, there is provided a drawing apparatus which performs drawing on a substrate with a charged particle beam, including a transmission unit including a plurality of channels and configured to transmit drawing data via the plurality of channels, a plurality of storages respectively corresponding to the plurality of channels, and configured to respectively store the drawing data transmitted via the plurality of channels, and a controller configured to control at least either one of transmission start time and a transmission rate of the drawing data from the transmission unit with respect to each of the plurality of storages.

Further aspects of the present invention will become apparent from the following description of exemplary embodiments with reference to the attached drawings.

### BRIEF DESCRIPTION OF THE DRAWINGS

FIG. 1 is a schematic view showing the arrangement of a drawing apparatus as one aspect of the present invention.

FIG. 2 is a schematic block diagram showing the data processing system of the drawing apparatus shown in FIG. 1.

FIG. 3 is a schematic block diagram showing the main controller of the drawing apparatus shown in FIG. 1.

FIG. 4 is a timing chart showing an example of transmission of drawing data by the data processing system shown in FIG. 2.

FIG. 5 is a timing chart showing an example of transmission of drawing data by the data processing system shown in FIG. 2.

FIG. 6 is a schematic block diagram showing a data processing system in the first embodiment.

FIG. 7 is a timing chart showing an example of transmission of drawing data by the data processing system in the first embodiment.

FIG. 8 is a schematic block diagram showing a data processing system in the second embodiment.

FIG. 9 is a flowchart for explaining the operation of the data processing system in the second embodiment.

FIG. 10 is a timing chart showing an example of transmission of drawing data by the data processing system in the second embodiment.

FIG. 11 is a view showing an example of the overall arrangement of the drawing data generator of the drawing apparatus shown in FIG. 1.

### DESCRIPTION OF THE EMBODIMENTS

Preferred embodiments of the present invention will be described below with reference to the accompanying drawings. Note that the same reference numerals denote the same members throughout the drawings, and a repetitive description thereof will not be given.

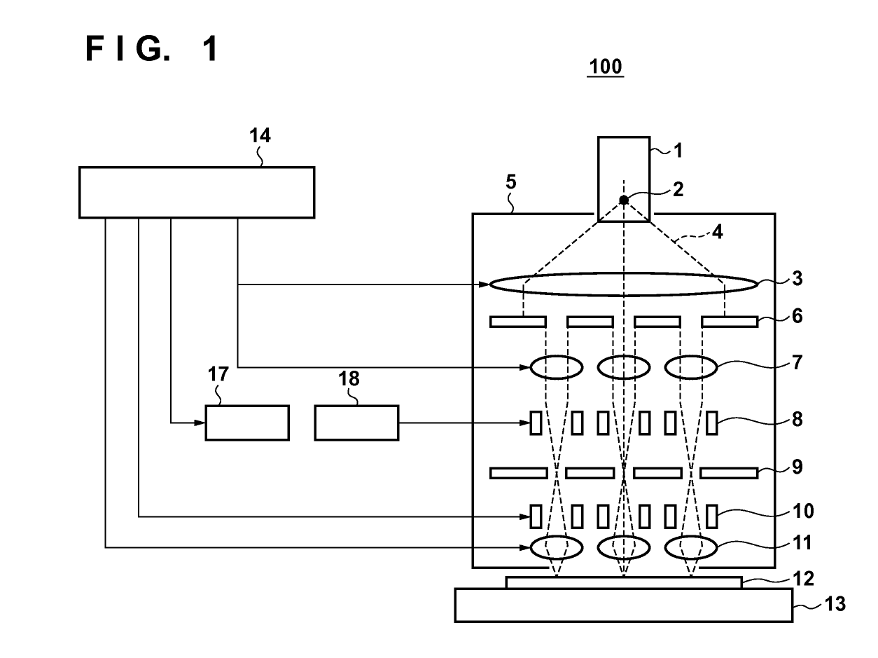

FIG. 1 is a schematic view showing the arrangement of a drawing apparatus (lithography apparatus) 100 as one aspect of the present invention. The drawing apparatus 100 is a drawing apparatus which performs drawing on a substrate with a charged particle beam. In the embodiment, the drawing apparatus 100 is implemented as a multi-charged particle beam drawing apparatus which draws a pattern on a substrate with a plurality of charged particle beams. The charged particle beam is not limited to an electron beam and may be an ion beam or the like.

The drawing apparatus 100 includes a charged particle source 1, collimator lens 3, aperture array 6, electrostatic lens 7, blanking deflector 8, blanking aperture 9, deflector 10, and electrostatic lens 11. The drawing apparatus 100 also includes a substrate stage 13, main controller 14, drawing data generator 17, and blanking controller 18. The collimator lens 3, aperture array 6, electrostatic lens 7, blanking deflector 8, blanking aperture 9, deflector 10, and electrostatic lens 11 are arranged in a column 5, and constitute a charged particle optical system.

The charged particle source 1 forms a crossover 2. A charged particle beam divergent from the crossover 2 is converted into an almost collimated charged particle beam via the collimator lens 3, and enters the aperture array 6 which constitutes the charged particle optical system. The aperture array 6 has a plurality of circular apertures arrayed in a matrix, and splits the charged particle beam having passed through the collimator lens 3 into a plurality of charged particle beams.

The charged particle beams having passed through the aperture array 6 enter the electrostatic lens 7 constituted by a plurality of electrode plates (for example, three electrode plates) each having a circular aperture. The blanking aperture 9 having a plurality of small apertures arrayed in a matrix is arranged at a position where a charged particle beam having passed through the electrostatic lens 7 forms first a crossover.

The blanking deflector 8 performs a blanking operation (switching between irradiation and non-irradiation of a substrate 12 with a charged particle beam) in cooperation with the blanking aperture 9 under the control of the blanking controller 18. The blanking controller 18 controls the blanking deflector 8 based on drawing data generated by the drawing data generator 17.

The charged particle beam having passed through the blanking aperture 9 is formed into an image via the electrostatic lens 11, forming an image corresponding to the crossover 2 on the substrate 12 held by the substrate stage 13. At this time, the charged particle beam having passed through the blanking aperture 9 is deflected by the deflector 10 interposed between the blanking aperture 9 and the electrostatic lens 11 (that is, an image formed on the substrate 12 is deflected).

The main controller 14 includes a CPU and memory, and controls the overall (operation of the) drawing apparatus 100. For example, when drawing a pattern on the substrate 12, the main controller 14 continuously moves the substrate stage 13 holding the substrate 12 in the X-axis direction. Then, the main controller 14 controls the deflector 10 to deflect an image formed on the substrate 12 in the Y-axis direction while controlling the blanking deflector 8 and blanking aperture 9 via the blanking controller 18 to blank a charged particle beam. As a result, a pattern is drawn on the substrate 12.

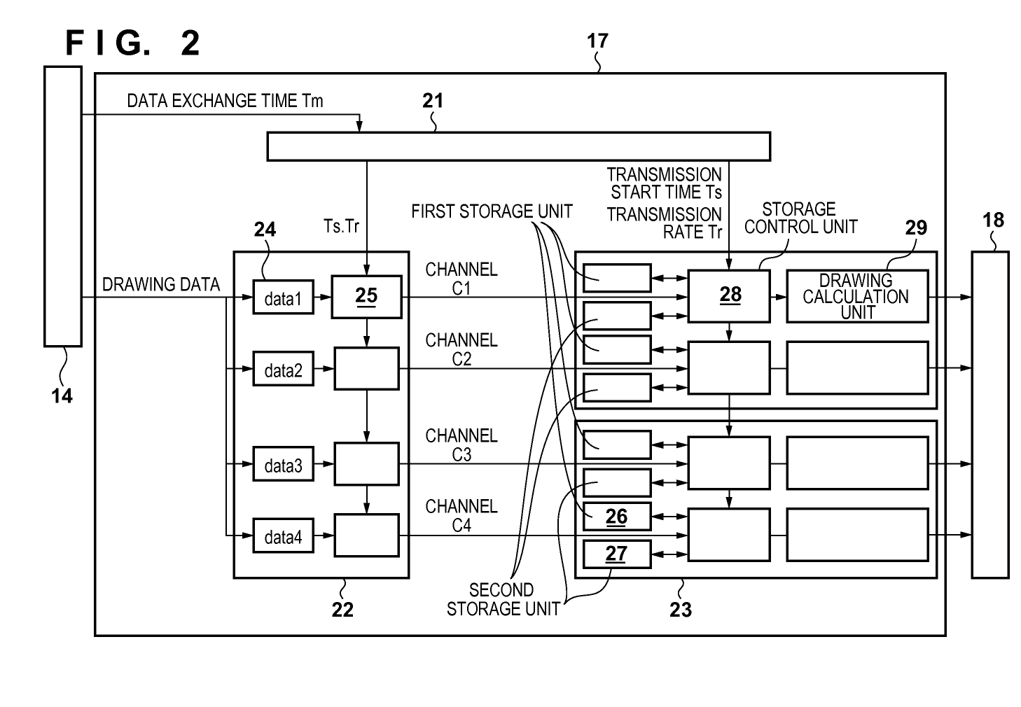

FIG. 2 is a schematic block diagram showing the data processing system of the drawing apparatus 100. Drawing data (data1, data2, data3, and data4) assigned to the respective channels (transmission paths or communication paths) of drawing data transmission units 25 are transmitted from the main controller 14 to a drawing data distribution unit 22 and stored in data storage units 24, respectively. The drawing data is vector data corresponding to a pattern to be drawn on a substrate. When data exchange time Tm for exchanging (switching) drawing data is supplied from the main controller 14 to a setting unit 21, the setting unit 21 sets transmission start time Ts and a transmission rate Tr of drawing data in the drawing data transmission units 25 to start transmission of drawing data. The drawing data transmission units 25 transmit, to a drawing data generation unit 23 via channels C1 to C4, the respective drawing data stored in the data storage units 24. The drawing data generation unit 23 includes, for each of the channels C1 to C4, a first storage unit 26 and second storage unit 27 which store drawing data, a storage control unit 28 which controls the first storage unit 26 and second storage unit 27, and a drawing calculation unit 29. The drawing data read from the first storage unit 26 or second storage unit 27 by the storage control unit 28 undergoes various correction calculations by the drawing calculation unit 29 and is transmitted to the blanking controller 18.

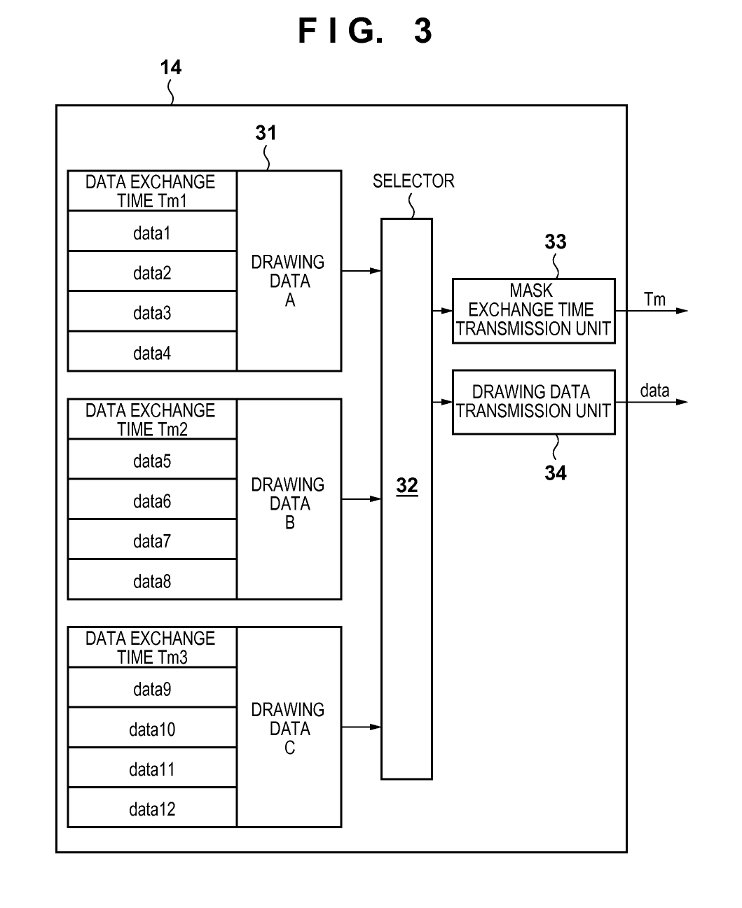

FIG. 3 is a schematic block diagram showing the main controller 14 of the drawing apparatus 100. The main controller 14 has a function of managing a plurality of drawing data to be used in the drawing apparatus 100, recipes describing the procedures of drawing processing and various correction parameters, and the like. The main controller 14 functions as a data server. Drawing data 31 contains the data exchange time Tm when exchanging drawing data, and drawing data “data” assigned to the respective channels C1 to C4. For example, in FIG. 3, the main controller 14 manages drawing data A, drawing data B, and drawing data C as the drawing data 31. The drawing data A contains the data exchange time Tm1 and drawing data (partial data corresponding to portions of a pattern to be drawn on a substrate) data1 to data4. The drawing data B contains the data exchange time Tm2 and drawing data (partial data corresponding to portions of a pattern to be drawn on a substrate) data5 to data8. The drawing data C includes the data exchange time Tm3 and drawing data (partial data corresponding to portions of a pattern to be drawn on a substrate) data9 to data12. Note that the number of drawing data manageable by the main controller 14 is not limited to three. A selector 32 selects drawing data to be used in the drawing apparatus from the drawing data A, drawing data B, and drawing data C. The data exchange time Tm and drawing data “data” contained in the drawing data selected by the selector 32 are transmitted (supplied) to the drawing data generator 17 via a data exchange time transmission unit 33 and drawing data transmission unit 34, respectively.

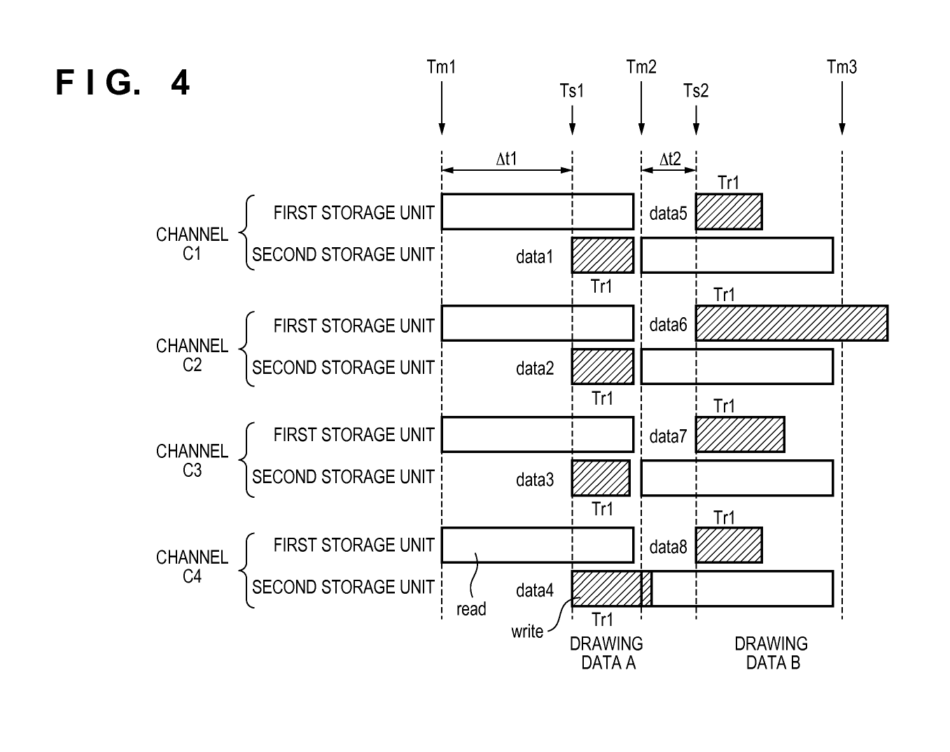

FIG. 4 is a timing chart showing an example of transmission of drawing data by the data processing system shown in FIG. 2. In FIG. 4, a hatched portion represents a state in which the storage control unit 28 performs write of drawing data in the first storage unit 26 or second storage unit 27. A blank portion represents a state in which the storage control unit 28 performs read of drawing data from the first storage unit 26 or second storage unit 27. Assume that drawing data have been transmitted to and stored in the first storage units 26 corresponding to the channels C1 to C4 by the data exchange time Tm1.

Referring to FIG. 4, at the data exchange time Tm1, the storage control unit 28 reads drawing data from the first storage unit 26, the drawing calculation unit 29 performs various correction calculations for the drawing data, and the resultant drawing data is transmitted to the blanking controller 18, thereby starting drawing. Then, the data exchange time Tm2 is supplied to the setting unit 21 to set the transmission rate Tr1 and the transmission start time Ts1 of drawing data to the second storage unit 27. The data amount of drawing data differs between the respective channels in accordance with the density of a drawing pattern. Thus, for example, when the data amount is large, like the drawing data data4 contained in the drawing data A, transmission may not end by the data exchange time Tm2.

To avoid this, the transmission start time Ts2 of drawing data may be brought close to the data exchange time Tm2. However, for example, when the data amount is excessively large, like the drawing data data6 contained in the drawing data B, even if a standby time Δt2 is set to be 0, transmission may not end by the data exchange time Tm3. Even if transmission ends by the data exchange time Tm3, a new problem to be described below may arise.

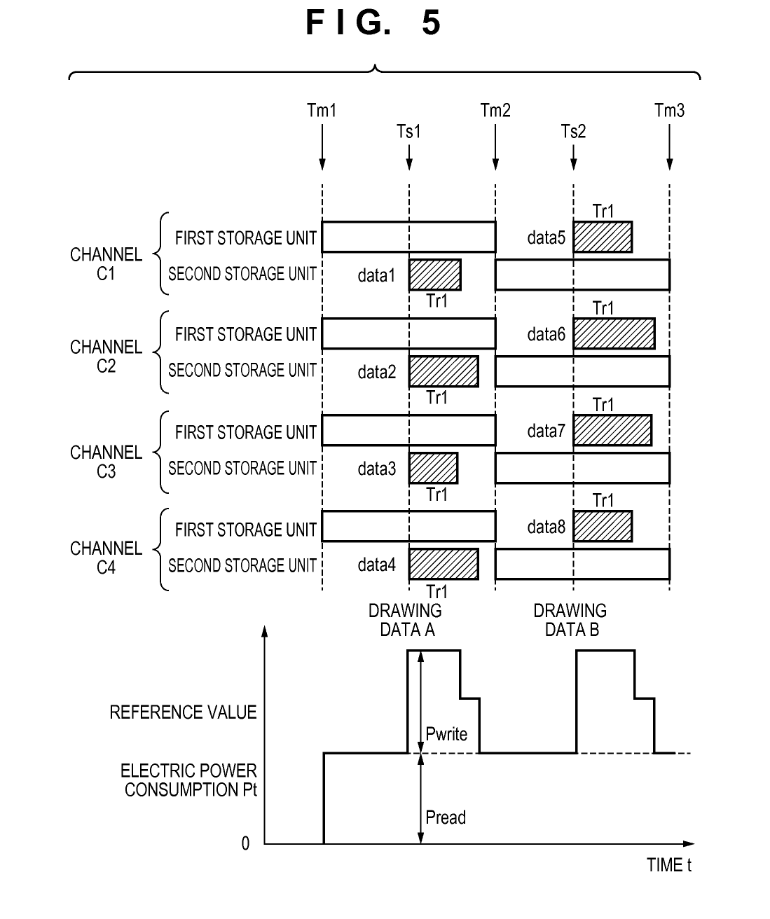

FIG. 5 is a timing chart showing an example of transmission of drawing data by the data processing system shown in FIG. 2. Referring to FIG. 5, at the data exchange time Tm1, drawing data is read from the first storage unit 26, starting drawing. At the data transmission start time Ts1, write of drawing data in the second storage unit 27 starts. At this time, electric power consumption Pwrite required to write drawing data in the second storage unit 27 is added to electric power consumption Pread required to read drawing data from the first storage unit 26. As a result, the electric power consumption at the data transmission start time Ts1 increases, as shown in FIG. 5. In other words, the electric power consumption peaks (peak electric power) at the data transmission start time Ts1. If a large-size power supply is installed in accordance with such electric power consumption (peak electric power), this increases the cost and installation area of the drawing apparatus 100. Further, large electric power consumption generates noise and may cause a malfunction of an electric circuit or the like.

By constituting the data processing system in the drawing apparatus 100, as described in each of the following embodiments, a drawing apparatus advantageous for transmitting drawing data corresponding to a pattern to be drawn on a substrate is implemented.

### First Embodiment

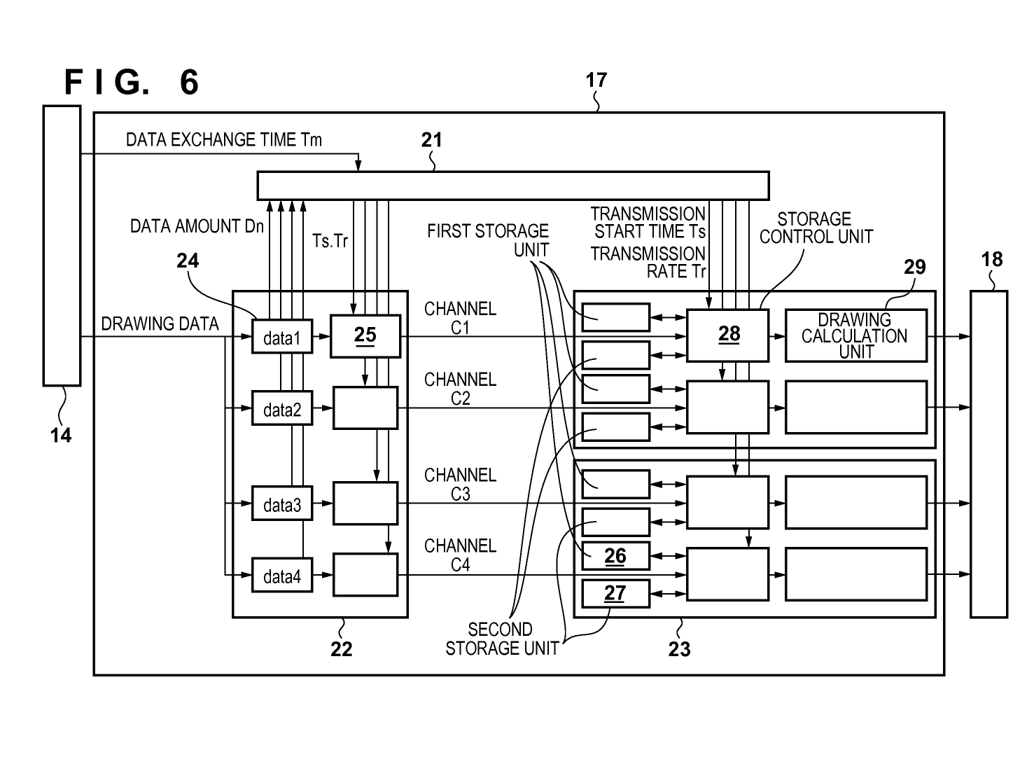

FIG. 6 is a schematic block diagram showing the data processing system of a drawing apparatus 100 in the first embodiment of the present invention. Here, a case in which drawing data transmission units 25 include four channels C1 to C4 as channels for transmitting drawing data will be exemplified. However, the present invention is not limited to this.

Drawing data (data1, data2, data3, and data4) assigned to the respective channels of the drawing data transmission units 25 are transmitted from a main controller 14 to a drawing data distribution unit 22 and stored in data storage units 24, respectively. The data storage unit 24 is generally constructed by a large-capacity hard disk drive or the like.

In the embodiment, a setting unit 21 is configured to set transmission start time Ts and a transmission rate T r of drawing data independently for each drawing data transmission unit 25 and each storage control unit 28. The main controller 14 supplies, to the setting unit 21, a data amount Dn of drawing data for each channel, and data exchange time Tm when exchanging (switching) drawing data.

The setting unit 21 decides and sets the transmission start time Ts and transmission rate Tr for each channel so that transmission of drawing data in all the channels C1 and C2 will end by the data exchange time Tm. In other words, the setting unit 21 controls, independently for each channel, at least either of the transmission start time Ts and transmission rate Tr when the drawing data transmission unit 25 transmits drawing data to each of a first storage unit 26 and second storage unit 27. The main controller 14 may incorporate the setting unit 21 (that is, the main controller 14 may implement the function of the setting unit 21). Note that transmission of drawing data includes write of drawing data in the first storage unit 26 or second storage unit 27.

The drawing data transmission unit 25 transmits, to a drawing data generation unit 23, each drawing data stored in the data storage unit 24. In the embodiment, the drawing data generation unit 23 includes two channels. The drawing data generation unit 23 includes, for each of the channels C1 to C4, the first storage unit 26 and second storage unit 27 which store drawing data, the storage control unit 28 which controls the first storage unit 26 and second storage unit 27, and a drawing calculation unit 29. Each of the first storage unit 26 and second storage unit 27 is constructed by a DRAM (Dynamic Random Access Memory) or the like because high-speed read is necessary. The drawing data read from the first storage unit 26 or second storage unit 27 by the storage control unit 28 undergoes various correction calculations by the drawing calculation unit 29 and is transmitted to a blanking controller 18.

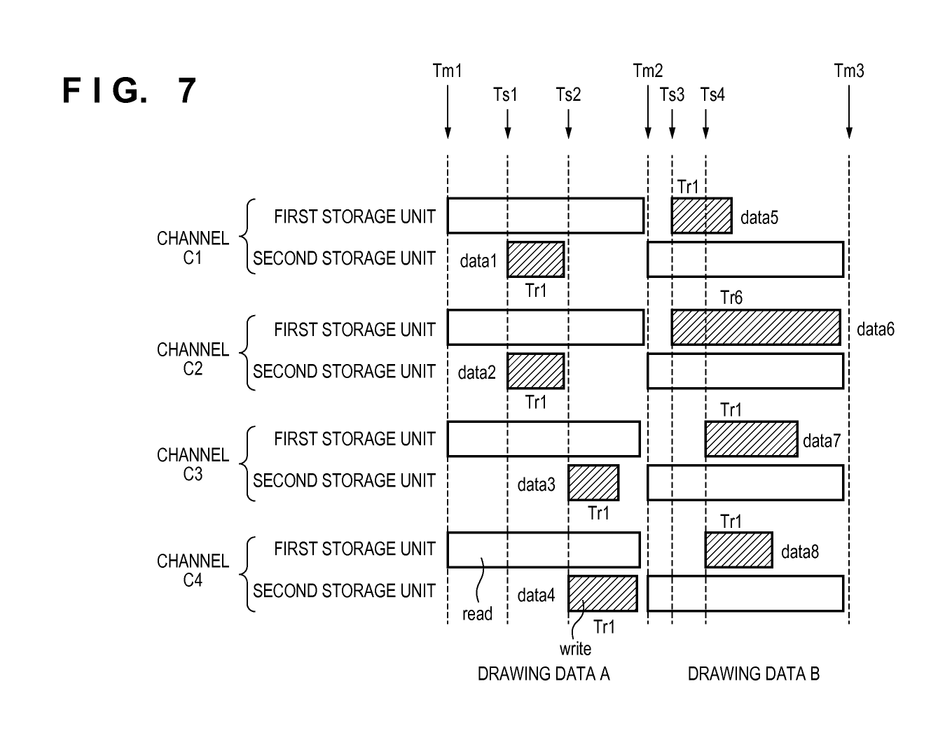

FIG. 7 is a timing chart showing an example of transmission of drawing data by the data processing system in the first embodiment. In FIG. 7, a hatched portion represents a state in which the storage control unit 28 performs write of drawing data in the first storage unit 26 or second storage unit 27. A blank portion represents a state in which the storage control unit 28 performs reading out of drawing data from the first storage unit 26 or second storage unit 27. As an example of transmission of drawing data, a case in which drawing data is transmitted in the unit of the drawing data generation unit 23 will be explained.

Assume that drawing data are written in the first storage unit 26 and second storage unit 27 at the same transmission rate Tr1 in the period from the data exchange time Tm1 to the data exchange time Tm2. There are two transmission start times Ts1 and Ts2 of drawing data, and drawing data are transmitted in the unit of the drawing data generation unit 23. Drawing data are transmitted via the channels C1 and C2 at the transmission start time Ts1, and via the channels C3 and C4 at the transmission start time Ts2.

In the period from the data exchange time Tm2 to the data exchange time Tm3, the data amount Dn of each channel of drawing data B has been supplied in advance to the setting unit 21, revealing that the data amount of drawing data data6 is large. Based on the data amount of the drawing data data6 contained in the drawing data B, the setting unit 21 decides the transmission start time Ts3 and transmission rate Tr6 so that transmission of drawing data will end by the data exchange time Tm3. In other words, the setting unit 21 decides at least either of the transmission start time Ts and transmission rate Tr for each channel based on the transmission time of drawing data for each channel and the data amount of drawing data for each channel.

As described above, according to the first embodiment, the transmission start time Ts and transmission rate Tr can be set in accordance with the data amount for each channel. Even if the data amount of drawing data varies between the respective channels, transmission of drawing data to the first storage unit 26 or second storage unit 27 can end in a predetermined period.

### Second Embodiment

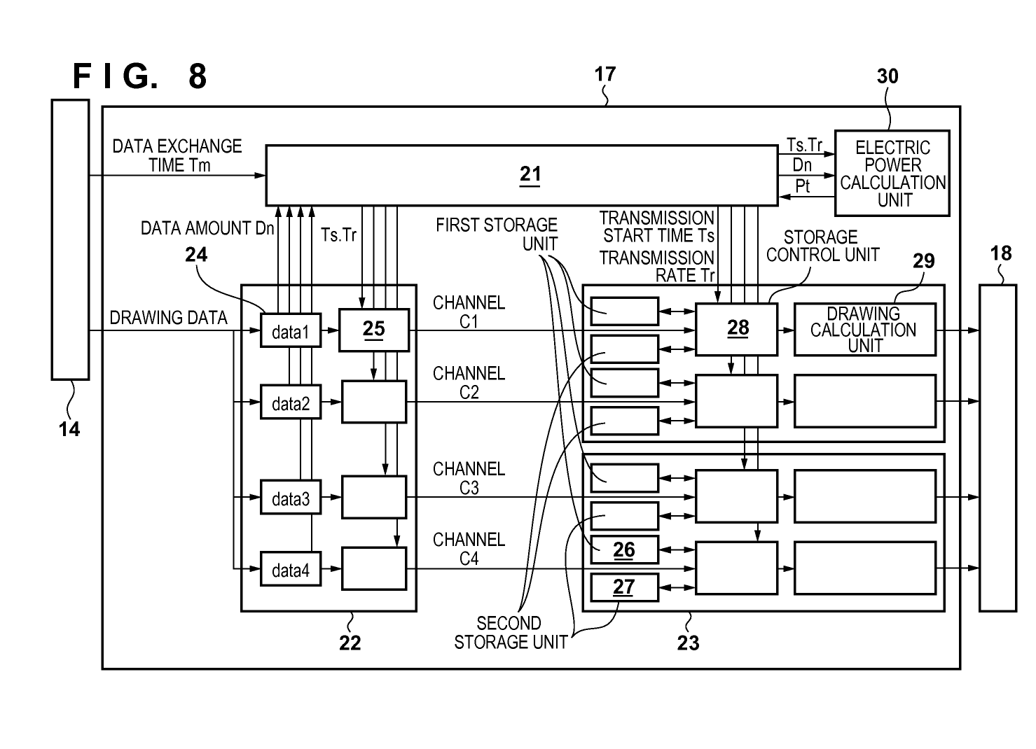

FIG. 8 is a schematic block diagram showing the data processing system of a drawing apparatus 100 in the second embodiment of the present invention. In the second embodiment, an electric power calculation unit 30 is further added to the data processing system in the first embodiment shown in FIG. 6. Based on a data amount Dn, transmission start time Ts, and a transmission rate Tr transmitted from a setting unit 21 for each channel, the electric power calculation unit 30 calculates electric power consumption Pt at each of a plurality of times in each of first storage units 26 and second storage units 27. When each of the first storage unit 26 and second storage unit 27 is constructed by a DRAM, electric current consumption and an application voltage are obtained from a data sheet as long as the transmission rate (operating clock) is decided. Since the time taken to transmit drawing data can be obtained from the data amount Dn and transmission rate Tr, the electric power consumption Pt at each time in each of the first storage unit 26 and second storage unit 27 can be calculated by taking account of the transmission start time Ts. As for the electric current consumption, an electric current consumed by each of the first storage unit 26 and second storage unit 27 each constructed by a DRAM may be directly measured by an ammeter. A main controller 14 may incorporate the setting unit 21 and electric power calculation unit 30 (that is, the main controller 14 may implement the functions of the setting unit 21 and electric power calculation unit 30).

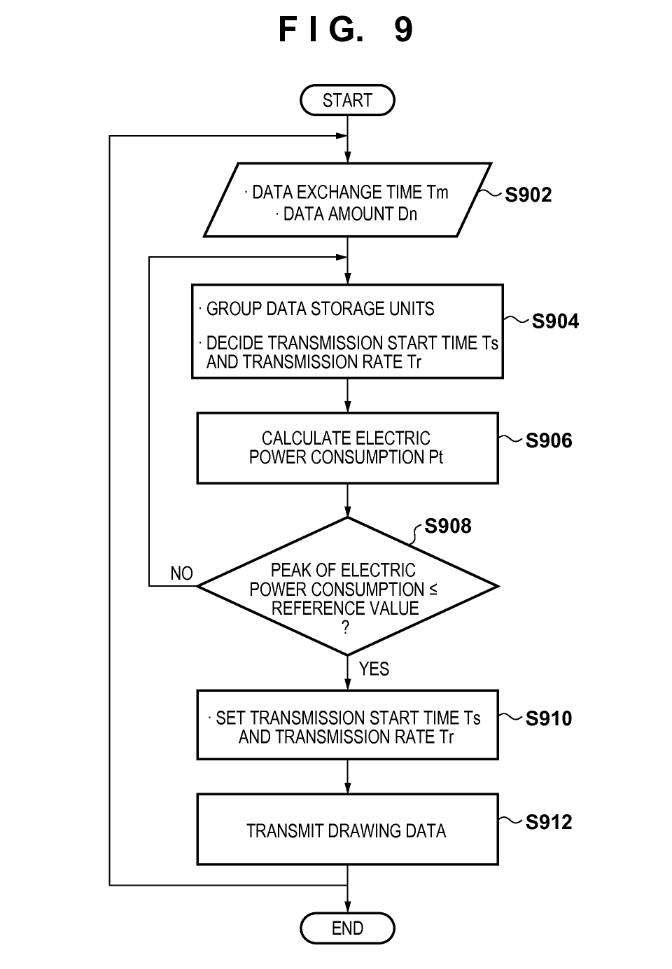

FIG. 9 is a flowchart for explaining the operation of the data processing system in the second embodiment. In step S902, the main controller 14 transmits data exchange time Tm to the setting unit 21, and a drawing data distribution unit 22 transmits the data amount Dn for each channel to the setting unit 21.

In step S904, the setting unit 21 divides the data storage units 24 into a plurality of groups in the transmission unit of drawing data, and decides the transmission start time Ts and transmission rate Tr so that transmission of drawing data in each channel will end by the next data exchange time Tm.

In step S906, the electric power calculation unit 30 calculates the electric power consumption Pt at each time in each of the first storage unit 26 and second storage unit 27, based on the transmission start time Ts and transmission rate Tr decided in step S904 and the data amount Dn for each channel.

In step S908, the setting unit 21 determines whether the peak of the electric power consumption Pt calculated in step S906 is equal to or lower than a reference value (that is, whether the reference is met). If the peak of the electric power consumption Pt exceeds the reference value, the process returns to step S904 to decide again the transmission start time Ts and transmission rate Tr. This loop is repeated until the peak of the electric power consumption Pt becomes equal to or lower than the reference value. If the peak of the electric power consumption Pt is equal to or lower than the reference value, the process shifts to step S910.

In step S910, the setting unit 21 sets, for drawing data transmission units 25 and storage control units 28, the transmission start time Ts and transmission rate Tr decided in step S904.

In step S912, each drawing data transmission unit 25 transmits drawing data via a corresponding one of the channels C1 to C4 based on the transmission start time Ts and transmission rate Tr set in step S910. Each storage control unit 28 stores the transmitted drawing data in the first storage unit 26 or second storage unit 27.

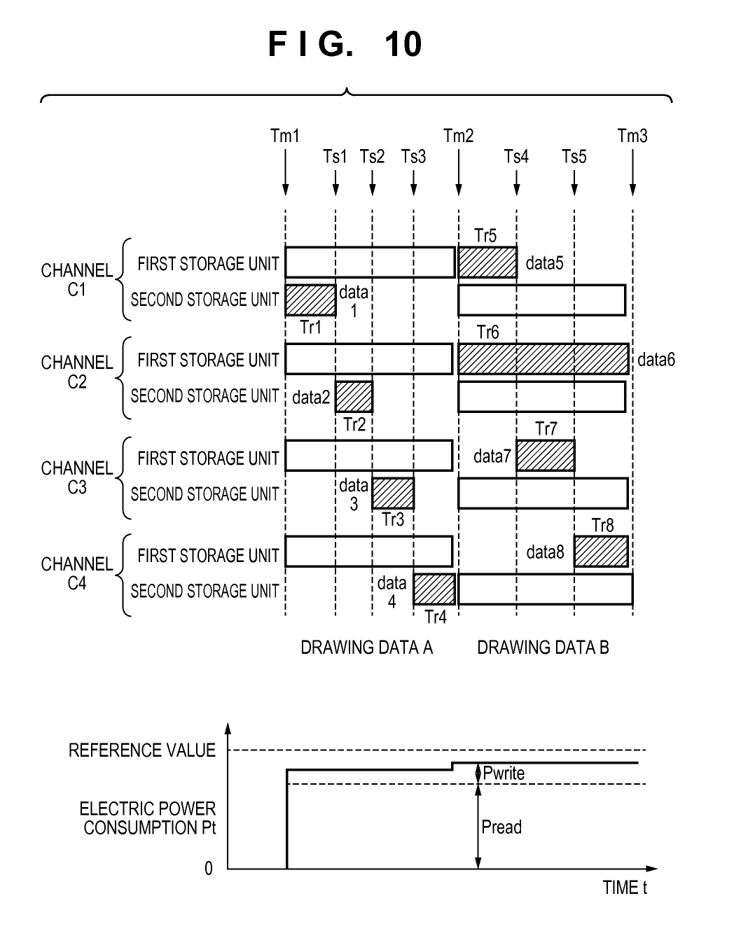

FIG. 10 is a timing chart showing an example of transmission of drawing data by the data processing system in the second embodiment. In the second embodiment, the transmission start time Ts and transmission rate Tr optimized based on the electric power consumption Pt calculated by the electric power calculation unit 30 are set for each channel.

For example, for drawing data A, when write of all drawing data in the second storage units 27 is series-processed in time division for the respective channels, data processing per unit time can be leveled. At this time, electric power consumption Pwrite required to write drawing data in the second storage unit 27 is added to electric power consumption Pread required to read drawing data from the first storage unit 26. However, the peak of the electric power consumption Pt is set to be equal to or lower than the reference value. Thus, the electric power consumption Pt does not peak and can be decreased. As for drawing data B, transmission of drawing data data6 and transmission of drawing data data5, data7, and data8 can be parallelly processed. Even in this case, data processing can be leveled, and the peak value of the electric power consumption Pt can be reduced.

The storage control unit 28 controls the operations of the first storage unit 26 and second storage unit 27 to switch between the first processing and second processing regarding storage of drawing data at the timing when transmission of drawing data corresponding to one pattern to be drawn on a substrate ends. The first processing is processing of parallelly performing an operation of reading out drawing data stored in the first storage unit 26 and an operation of storing drawing data in the second storage unit 27. The second processing is processing of parallelly performing an operation of reading out drawing data stored in the second storage unit 27 and an operation of storing drawing data in the first storage unit 26.

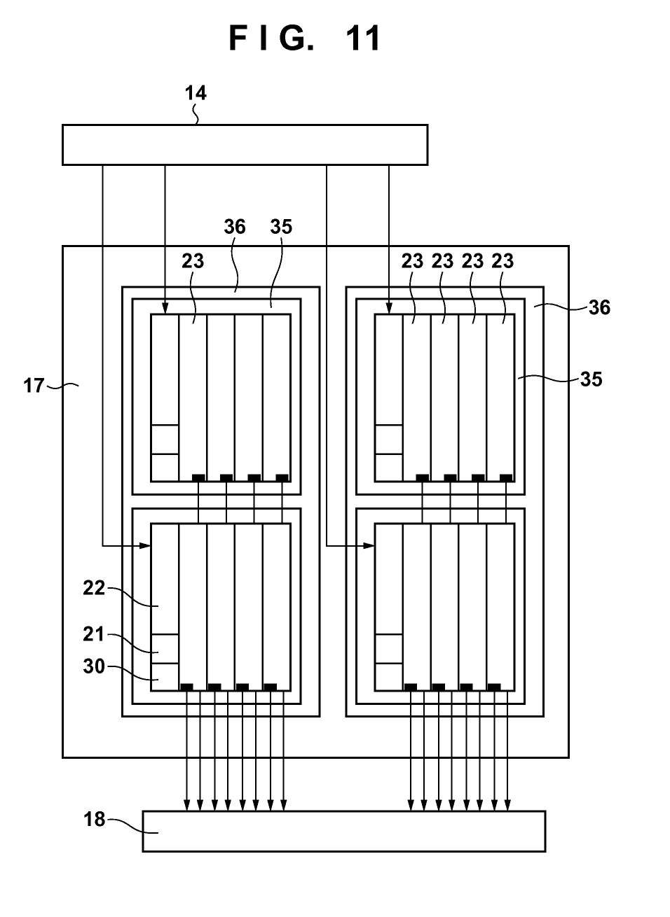

FIG. 11 is a view showing an example of the overall arrangement of a drawing data generator 17. Drawing data generation units 23 are mounted on a printed board or the like, and the printed board or the like on which the drawing data generation units 23 are mounted is mounted in a subrack 35. The number of printed boards changes depending on the circuit scale of a blanking controller 18. In many cases, a plurality of printed boards are mounted on the subrack 35. The setting unit 21, drawing data distribution unit 22, and electric power calculation unit 30 are similarly mounted on a printed board and mounted on the same subrack 35. A plurality of subracks 35 are mounted in a rack 36, and a plurality of racks 36 constitute the drawing data generator 17. As the division unit for dividing drawing data in step S904 shown in FIG. 9 (that is, the processing unit for drawing data corresponding to one pattern to be drawn on a substrate), the printed board unit, subrack unit, or rack unit is conceivable. If the division unit (transmission unit) of drawing data is subdivided to perform time division processing, the electric power consumption Pt can be reduced, but the management of the transmission start time Ts becomes complicated.

As described above, the drawing apparatus 100 is advantageous for transmitting drawing data corresponding to a pattern to be drawn on a substrate, and thus is, for example, suitable for manufacturing a microdevice such as a semiconductor device, and an article such as an element having a microstructure. The method of manufacturing an article includes a step of forming a latent image pattern on a photosensitive agent applied to a substrate by using the drawing apparatus 100 (a step of performing drawing on a substrate), and a step of developing the substrate on which the latent image pattern is formed in the preceding step (a step of developing the substrate on which the drawing has been performed). Further, the manufacturing method can include other well-known steps (for example, oxidization, deposition, vapor deposition, doping, planarization, etching, resist removal, dicing, bonding, and packaging). The method of manufacturing an article according to the embodiment is superior to a conventional method in at least one of the performance, quality, productivity, and production cost of an article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-079925 filed on Apr. 5, 2013, which is hereby incorporated by reference herein in its entirety.

What is claimed is:

1. A drawing apparatus which performs drawing on a substrate with a charged particle beam, comprising:
a transmission unit including a plurality of channels and configured to transmit drawing data via the plurality of channels;
a plurality of storages respectively corresponding to the plurality of channels, and configured to respectively store the drawing data transmitted via the plurality of channels; and
a controller (21;14) configured to control at least either one of transmission start time and a transmission rate of the drawing data from the transmission unit with respect to each of the plurality of storages.

2. The apparatus according to claim 1, wherein the controller is configured to determine the at least either one of the transmission start time and the transmission rate with respect to each of the plurality of storages based on at least either one of a transmission time or data amount of the drawing data with respect to each of the plurality of storages.

3. The apparatus according to claim 1, wherein the controller is configured to obtain electric power consumption of the plurality of storages at each of a plurality of times based on a data amount, the transmission start time, and the transmission rate of the drawing data with respect to each of the plurality of storages, and to determine whether the obtained electric power consumption satisfies a criterion.

4. The apparatus according to claim 3, wherein the controller is configured to determine again the at least either one of the transmission start time and the transmission rate with respect to each of the plurality of storages if the obtained electric power consumption does not satisfy the criterion.

5. The apparatus according to claim 1, wherein
the plurality of storages include a first storage and a second storage with respect to each of the plurality of channels, and
the controller is configured to control operations of the first storage and second storage such that switching is performed between first processing in which an operation of reading out the drawing data stored in the first storage and an operation of storing the drawing data in the second storage are performed in parallel, and second processing in which an operation of reading out the drawing data stored in the second storage and an operation of storing the drawing data in the first storage are performed in parallel.

6. The apparatus according to claim 1, wherein the drawing data stored in each of the plurality of storages is partial data corresponding to a part of a pattern to be drawn on the substrate.

7. The apparatus according to claim 6, further comprising a processor (29) including a plurality of processing units and configured to process the drawing data,
wherein the partial data corresponds to one of the plurality of processing units.

8. The apparatus according to claim 1, wherein the drawing data includes vector data.

9. A method of manufacturing an article, the method comprising steps of:
performing drawing on a substrate using a drawing apparatus;
developing the substrate on which the drawing has been performed; and
processing the developed substrate to manufacture the article,
wherein the drawing apparatus performs drawing on the substrate with a charged particle beam, and includes:
a transmission unit including a plurality of channels and configured to transmit drawing data via the plurality of channels;
a plurality of storages respectively corresponding to the plurality of channels, and configured to respectively store the drawing data transmitted via the plurality of channels; and
a controller (21;14) configured to control at least either one of transmission start time and a transmission rate of the drawing data from the transmission unit with respect to each of the plurality of storages.
